(19) United States
(12) Patent Application Publication
(10) Pub. No.: US 2025/0301843 A1
(43) Pub. Date: Sep. 25, 2025

(54) LED DEVICE WITH PROTECTION LAYER AND METHOD OF MANUFACTURING THE SAME

(71) Applicant: Lumileds LLC, San Jose, CA (US)

(72) Inventors: Ronja MISSONG, Aachen (DE); Matthias HEIDEMANN, Aachen (DE); Marcel Rene BOHMER, Eindhoven (NL); Sarah SOMMER, Aachen (DE); Hans-Helmut BECHTEL, Aachen (DE)

(73) Assignee: Lumileds LLC, San Jose, CA (US)

(21) Appl. No.: 19/207,654

(22) Filed: May 14, 2025

Related U.S. Application Data
(63) Continuation of application No. PCT/US2023/035639, filed on Oct. 20, 2023.
(60) Provisional application No. 63/430,862, filed on Dec. 7, 2022.

(51) Int. Cl. H10H 29/80; H10H 29/01; H10H 29/30

(52) U.S. Cl. CPC H10H 29/842; H10H 29/034; H10H 29/30

(57) ABSTRACT

A device and method of forming the device are disclosed herein. The device having a silicone layer disposed on an LED structure, the device further including an inorganic protection layer disposed on a surface of the phosphor layer opposite the LED structure. The method of forming the device includes using atomic layer deposition to deposit the inorganic protection layer on the silicone layer.

### CROSS-REFERENCE TO RELATED APPLICATION

This application is a continuation of International Patent Application No. PCT/US2023/035639 titled “LED DEVICE WITH PROTECTION LAYER AND METHOD OF MANUFACTURING THE SAME” and filed Oct. 20, 2023, which claims benefit of priority to U.S. Provisional Patent Application No. 63/430,862 titled “ALD LAYER TO COVER ADHESIVE SILICONE SURFACES” and filed Dec. 7, 2022. The foregoing applications are incorporated herein by reference in their entirety.

### FIELD OF THE INVENTION

The invention relates generally to an inorganic layer for protecting pcLEDs and pcLED arrays, light sources comprising such pcLEDs or pcLED arrays, displays comprising such pcLED arrays, and visualization systems comprising such displays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, matrices and light engines including automotive adaptive headlights, augmented-reality (AR) displays, virtual-reality (VR) displays, mixed-reality (MR) displays (AR, VR, and MR systems referred to herein as visualization systems), smart glasses and displays for mobile phones, smart watches, monitors and TVs, and flash illumination for cameras in mobile phones. Individual LEDs or pcLEDs in these architectures can have an area of a few square millimeters down to a few square micrometers (e.g., microLEDs) depending on the matrix or display sized and its pixel per inch requirements.

### SUMMARY

In one aspect, this specification discloses a device including a silicone layer disposed on an LED structure, the device also including an inorganic protection layer disposed on a surface of the silicone layer opposite the LED structure. The inorganic protection layer may include a metal oxide. The inorganic protection layer may include at least one of AlO₃, SiO₂, CrO₂, ZrO₂, HfO₂, and Ta₂O₅. The inorganic protection layer may be formed by atomic layer deposition. The inorganic protection layer may have a thickness of less than 100 nm. The inorganic protection layer may be configured to be transparent to wavelengths in the visible light range. The inorganic protection layer may be configured to have optical properties. The silicone layer may have a shore-A hardness of 50 or less. The silicone layer may include a phosphor material to form a phosphor conversion layer. The LED structure may include an array of LEDs, which array may include at least two individually addressable light emitting diodes, and may include a display configured to receive light emitted by the array of LEDs. The LED structure may be a microLED array having at least two, individually addressable light emitting diodes on a same substrate.

In another aspect, the specification discloses a method of forming a device, the method including forming a silicone layer on an LED structure, and forming an inorganic protection layer on a surface of the silicone layer opposite the LED structure. The inorganic protection layer may be formed using atomic layer deposition. The method may further include irradiating the silicone layer with ultraviolet light before atomic layer deposition of the inorganic protection layer. The method may further include exposing the silicone layer to ozone before atomic layer deposition of the inorganic protection layer.

The device disclosed herein may be used for example in the various devices and applications listed above in the Background section.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of LEDs or pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display system.

FIG. 7 shows a block diagram of an example visualization system.

FIG. 8A illustrates a cross-section of a pcLED device having a thin inorganic protection layer, and FIG. 8B is an expanded view of the area labelled “B” in FIG. 8A.

FIG. 9 illustrates prototypical two part atomic layer deposition (ALD) reaction using trimethylaluminum (TMA) to form Al₂O₃.

FIG. 10 illustrates a method of forming a pcLED device having a thin inorganic protection layer.

FIG. 11 illustrates a cross-section of an LED device with a silicone lens having a thin inorganic protection layer.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

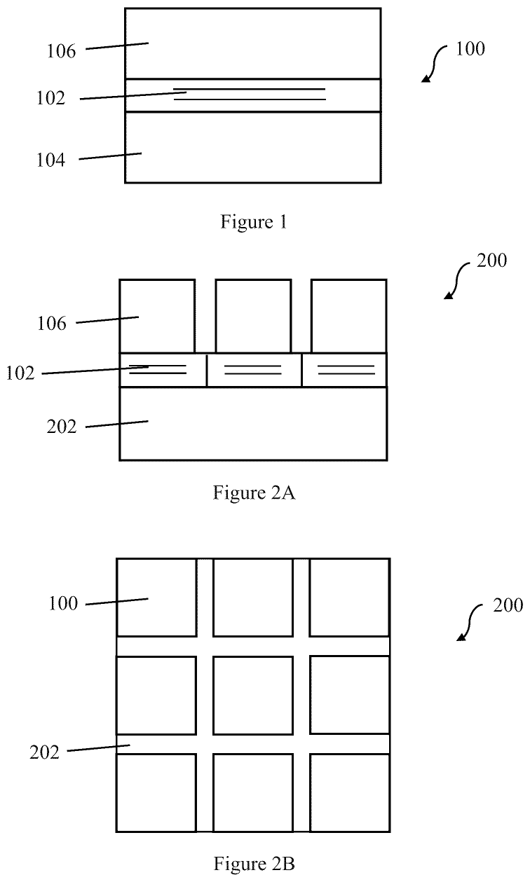

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used to form phosphor layer 106, depending on the desired optical output and color specifications from the pcLED. Phosphor layers may for example comprise phosphor particles dispersed in or bound to each other with a binder material or be or comprise a sintered ceramic phosphor plate. In phosphor layers 106 in which the phosphor particles are dispersed in a binder material, also referred to as a matrix material or matrix, silicones are frequently used at the matrix material due to good light extracting properties and general applicability of the material.

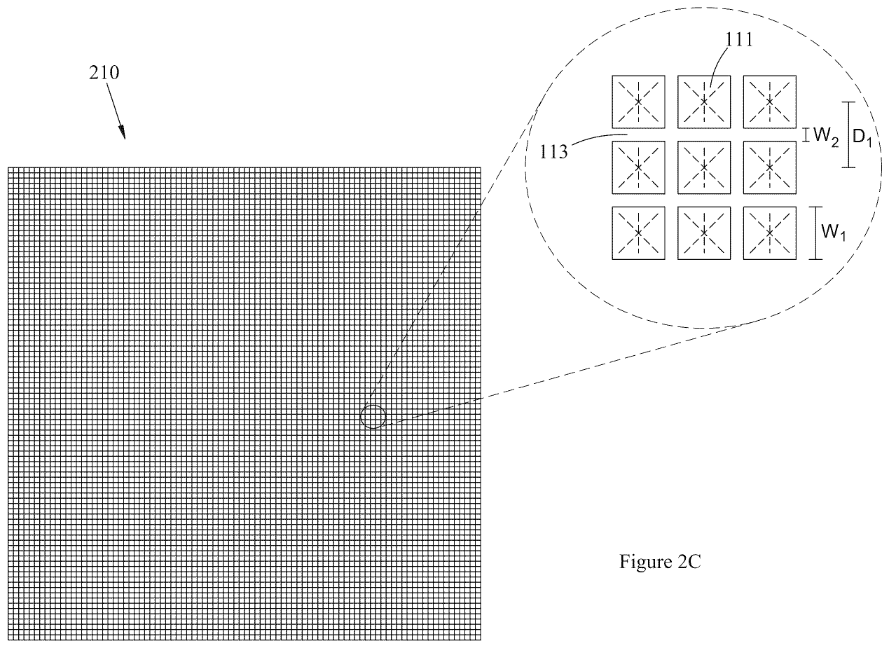

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W₁ are arranged as a square matrix with neighboring LEDs or pcLEDs having a center-to-center distances D₁ and separated by lanes 113 having a width W₂. W₁ may be, for example, less than or equal to 1 millimeter (mm), less than or equal to 500 microns, less than or equal to 100 microns, less than or equal to 50 microns, or less than or equal to 10 microns. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

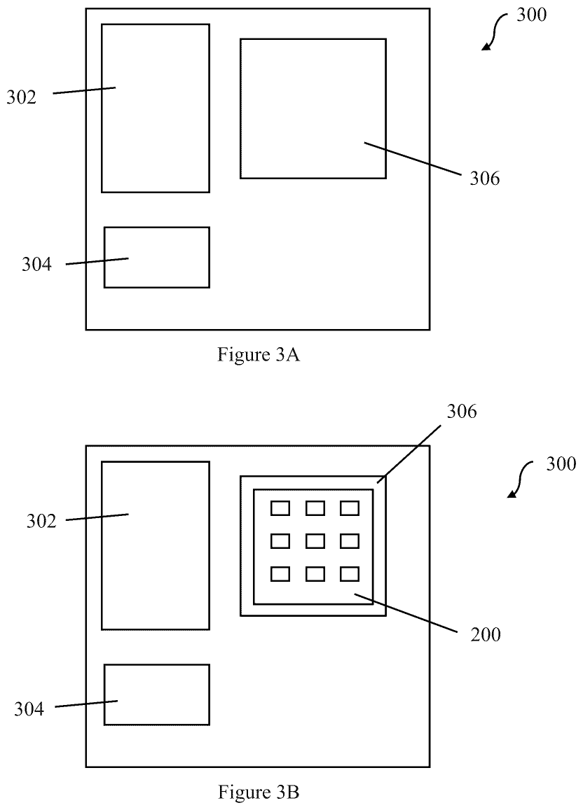

As shown in FIGS. 3A-3B, an LED or pcLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

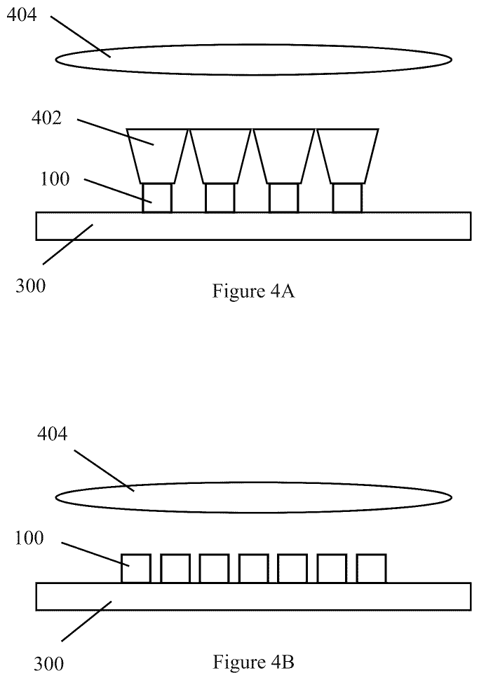

Individual LEDs or pcLEDs may optionally incorporate or be arranged in combination with a lens or other optical element located adjacent to or disposed on the LED or the phosphor layer of the pcLED. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distributions. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), AR, VR, and MR applications such as those described below.

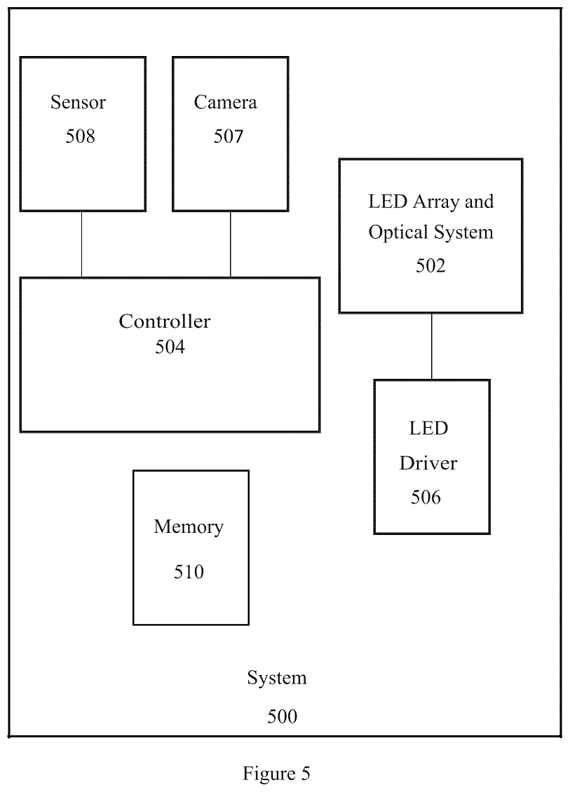

FIG. 5 schematically illustrates an example camera flash system 500 comprising an LED or pcLED array and an optical (e.g., lens) system 502, which may be or comprise an adaptive lighting system as described above in which LEDs or pcLEDs in the array may be individually operable or operable as groups. In operation of the camera flash system, illumination from some or all of the LEDs or pcLEDs in array and optical system 502 may be adjusted—deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

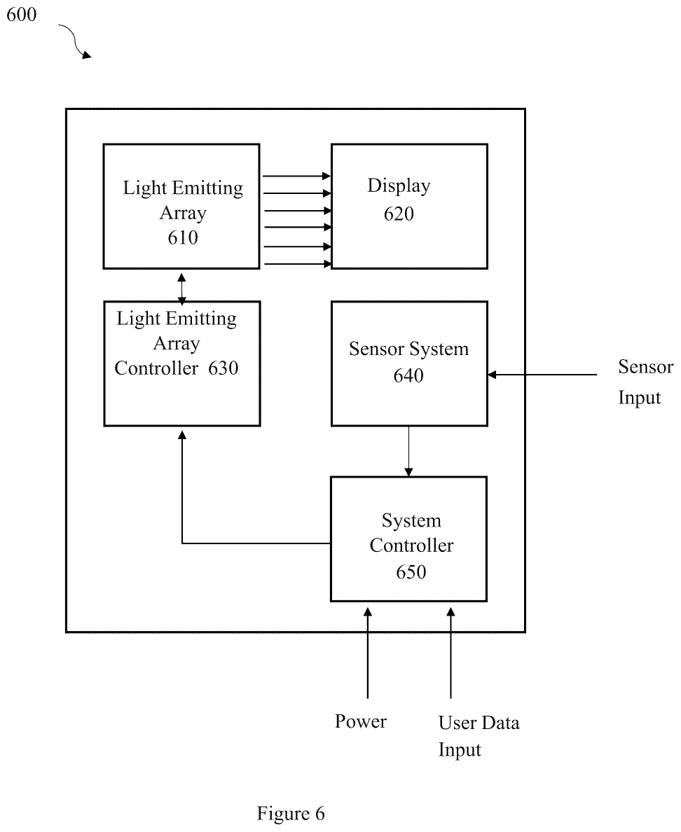

FIG. 6 schematically illustrates an example display system 600 that includes an array 610 of LEDs or pcLEDs that are individually operable or operable in groups, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 610 can be used to project light in graphical or object patterns that can for example support AR/VR/MR systems.

Sensor input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of a scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

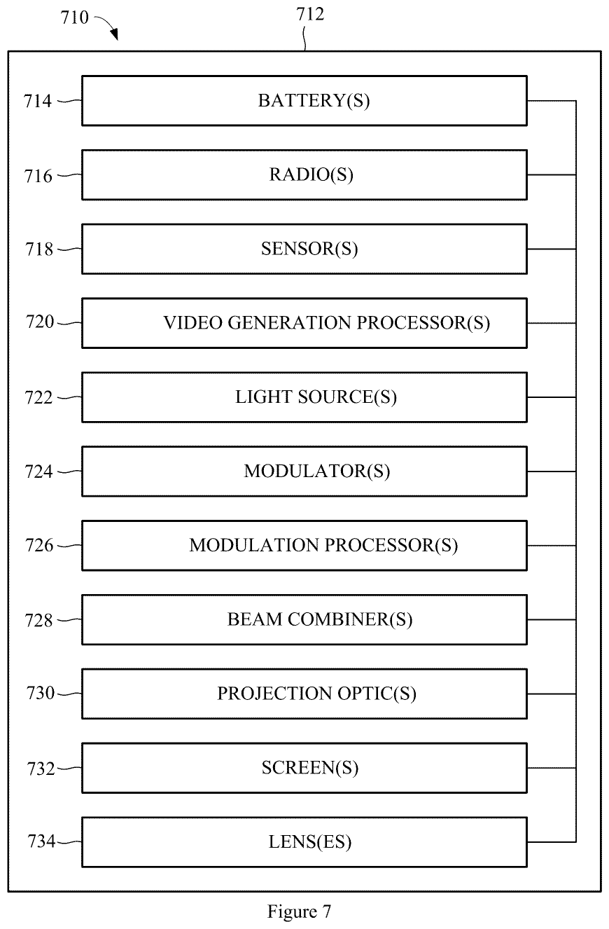

FIG. 7 shows a generalized block diagram of an example visualization system 710. The visualization system 710 can include a wearable housing 712, such as a headset or goggles. The housing 712 can mechanically support and house the elements detailed below. In some examples, one or more of the elements detailed below can be included in one or more additional housings that can be separate from the wearable housing 712 and couplable to the wearable housing 712 wirelessly and/or via a wired connection. For example, a separate housing can reduce the weight of wearable goggles, such as by including batteries, radios, and other elements. The housing 712 can include one or more batteries 714, which can electrically power any or all of the elements detailed below. The housing 712 can include circuitry that can electrically couple to an external power supply, such as a wall outlet, to recharge the batteries 714. The housing 712 can include one or more radios 716 to communicate wirelessly with a server or network via a suitable protocol, such as WiFi.

The visualization system 710 can include one or more sensors 718, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 718 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 718 can capture a real-time video image of the surroundings proximate a user.

The visualization system 710 can include one or more video generation processors 720. The one or more video generation processors 720 can receive, from a server and/or a storage medium, scene data that represents a three-dimensional scene, such as a set of position coordinates for objects in the scene or a depth map of the scene. The one or more video generation processors 720 can receive one or more sensor signals from the one or more sensors 718. In response to the scene data, which represents the surroundings, and at least one sensor signal, which represents the location and/or orientation of the user with respect to the surroundings, the one or more video generation processors 720 can generate at least one video signal that corresponds to a view of the scene. In some examples, the one or more video generation processors 720 can generate two video signals, one for each eye of the user, that represent a view of the scene from a point of view of the left eye and the right eye of the user, respectively. In some examples, the one or more video generation processors 720 can generate more than two video signals and combine the video signals to provide one video signal for both eyes, two video signals for the two eyes, or other combinations.

The visualization system 710 can include one or more light sources 722 that can provide light for a display of the visualization system 710. Suitable light sources 722 can include any of the LEDs, pcLEDs, LED arrays, and pcLED arrays discussed above, for example those discussed above with respect to display system 600.

The visualization system 710 can include one or more modulators 724. The modulators 724 can be implemented in one of at least two configurations.

In a first configuration, the modulators 724 can include circuitry that can modulate the light sources 722 directly. For example, the light sources 722 can include an array of light-emitting diodes, and the modulators 724 can directly modulate the electrical power, electrical voltage, and/or electrical current directed to each light-emitting diode in the array to form modulated light. The modulation can be performed in an analog manner and/or a digital manner. In some examples, the light sources 722 can include an array of red light-emitting diodes, an array of green light-emitting diodes, and an array of blue light-emitting diodes, and the modulators 724 can directly modulate the red light-emitting diodes, the green light-emitting diodes, and the blue light-emitting diodes to form the modulated light to produce a specified image.

In a second configuration, the modulators 724 can include a modulation panel, such as a liquid crystal panel. The light sources 722 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 724 can include multiple modulation panels that can modulate different colors of light. For example, the modulators 724 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 724 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 710 can include one or more modulation processors 726, which can receive a video signal, such as from the one or more video generation processors 720, and, in response, can produce an electrical modulation signal. For configurations in which the modulators 724 directly modulate the light sources 722, the electrical modulation signal can drive the light sources 724. For configurations in which the modulators 724 include a modulation panel, the electrical modulation signal can drive the modulation panel.

The visualization system 710 can include one or more beam combiners 728 (also known as beam splitters 728), which can combine light beams of different colors to form a single multi-color beam. For configurations in which the light sources 722 can include multiple light-emitting diodes of different colors, the visualization system 710 can include one or more wavelength-sensitive (e.g., dichroic) beam splitters 728 that can combine the light of different colors to form a single multi-color beam.

The visualization system 710 can direct the modulated light toward the eyes of the viewer in one of at least two configurations. In a first configuration, the visualization system 710 can function as a projector, and can include suitable projection optics 730 that can project the modulated light onto one or more screens 732. The screens 732 can be located a suitable distance from an eye of the user. The visualization system 710 can optionally include one or more lenses 734 that can locate a virtual image of a screen 732 at a suitable distance from the eye, such as a close-focus distance, such as 500 mm, 750 mm, or another suitable distance. In some examples, the visualization system 710 can include a single screen 732, such that the modulated light can be directed toward both eyes of the user. In some examples, the visualization system 710 can include two screens 732, such that the modulated light from each screen 732 can be directed toward a respective eye of the user. In some examples, the visualization system 710 can include more than two screens 732. In a second configuration, the visualization system 710 can direct the modulated light directly into one or both eyes of a viewer. For example, the projection optics 730 can form an image on a retina of an eye of the user, or an image on each retina of the two eyes of the user.

For some configurations of augmented reality systems, the visualization system 710 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

As noted above with respect to FIG. 1, silicones are often used as the matrix material between phosphor converter grains in the phosphor layer 106 of a pcLED. Under operation, LEDs release heat. Because of the different coefficients of thermal expansion (abbreviated herein as “CTE”) of the interacting materials in the pcLED, such as the surface of the LED structure 102 in contact with the phosphor layer 106, and the phosphor particles with the matrix material, deterioration of the pcLED may occur. Such deterioration may include, for instance, structural deterioration, such as delamination of the various layers, and/or cracking within the layers.

To prevent delamination and cracking in pcLEDs, highly flexible silicones having a low Shore hardness value are of special interest for use as the matrix material in the phosphor layers. Such low Shore hardness value silicones may include silicones having a shore hardness of, for example, 50 or below on the Shore-A hardness scale (i.e., hardness≤50 A) or for example having a Shore-A hardness of less than 30 (i.e., hardness<30 A).

Silicones with a low shore hardness value (e.g., hardness≤50 A, or hardness<30 A), however, tend to have an adhesive surface, and dust particles, fluffs, and other debris may stick to the adhesive surface of the silicone matrix material of the phosphor layer. Such dust particles, fluff's, and other debris can cause problems for LED applications, and in particular arrays of LEDs, as the dust, fluffs, and/or debris that adheres to the surface of the phosphor layer 106 can shadow and block light from individual LEDs, and cause failure of the device due to the blocked light. In particular, in microLEDs, a single dust particle can block light emitted from an

De No.

individual LED or group of LEDs in the array as each LED is small, and, for example, in a display system including the microLED array, the blocked light can significantly impact the quality of the projection of light. Therefore, LED surfaces, and in particular microLED surfaces, need to be prevented from collecting dust, fluffs, and other debris. Therefore, to effectively use the highly flexible silicones having low Shore hardness in pcLEDs, a way to prevent adhesion of dust, fluffs, and other debris from the surface of the pcLED is required.

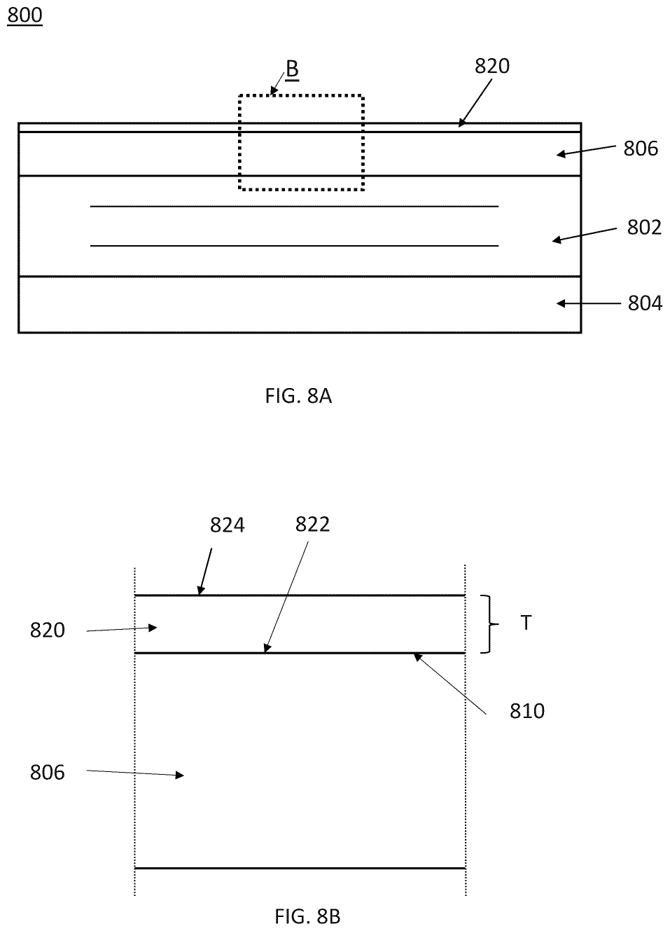

FIG. 8A illustrates a cross-section of a pcLED device having a thin inorganic protection layer, and FIG. 8B is an expanded view of the area labelled “B” in FIG. 8A.

In FIG. 8A, pcLED device 800 includes an LED structure 802. LED structure 802 may be an individual LED such as, for example, the LED structure 102 described with respect to FIG. 1. LED structure 802 may be an LED array or microLED array, such as, for example, array 200 described with respect to FIG. 2A or LED wafer 210 described with respect to FIG. 2C. LED structure 802 may be disposed on substrate 804.

A phosphor layer 806 may be disposed on LED structure 802. Phosphor layer 806 may include a phosphor material disposed in a matrix material. The phosphor material may be, for example, any phosphor particles having wavelength converting properties as are known by persons having ordinary skill in the art. The matrix material may be, for example, a silicone. Silicones used for matrix material in phosphor layer 806 may be a silicone material having a low Shore hardness, for example, Shore-A hardness of 50 or less, or for example less than 30, as described above.

As shown in FIG. 8A and 8B, a thin inorganic protection layer 820 may be disposed on the silicone matrix material of the phosphor layer 806 such that lower surface 822 of the inorganic protection layer 820 is disposed on surface 810 of the phosphor layer 806 that is opposite the LED structure 802. Thin inorganic protection layer 820 may be in direct contact with the phosphor layer 806, and encase the silicone matrix material of the phosphor layer 806. For example, inorganic protection layer 820 may cover any regions of the silicone layer which transmits light emitted from the LED structure, and which may be exposed to ambient surroundings, for example air (air which may contain dust, fluffs, and other debris). Inorganic protection layer 820 protects the phosphor layer 806 from collecting dust, fluffs, and other debris, by preventing such dust, fluffs, and debris from adhering to the matrix material of the phosphor layer 806. An upper surface 824 of the inorganic protection layer 820 may be in contact with ambient surroundings (e.g. air) or may be disposed under a lens or other feature needed for the application in which pcLED device 800 is used.

Inorganic protection layer 820 may be formed of a material that is optically transparent to the wavelengths of light LED structure 802 and phosphor layer 806 emit. For instance, when LED structure 802 and phosphor layer 806 are configured to emit visible light, the material forming the inorganic protection layer may be transparent to wavelengths between 380 nm and 780 nm. Likewise, if the LED structure 802 and phosphor layer 806 are configured to emit near infrared or infrared light, inorganic protection layer 820 may be transparent in the near infrared (800-2,500 nm) and/or infrared (3,000-25,000 nm) light wavelength ranges.

Examples of inorganic materials that may be used to form the inorganic protection layer 820 include, for example, AlO₃, SiO₂, CrO₂, ZrO₂, HfO₂, and Ta₂O₅. Depending on the application, a combination of two or more inorganic materials may be used. Such combination may, for instance be used to form an inorganic protection layer that is a mixture of two or more inorganic materials in a single layer. The inorganic protection layer 820 may also be formed as a multilayer, that is, a layer of a first inorganic material, such as, for example, AlO₃, followed by a layer of a second inorganic material, such as, for example, Ta₂O₅. Such a multilayer inorganic protection layer 820 may include multiple layers and multiple inorganic materials.

FIG. 8B shows the thickness T of the inorganic protection layer 820 between the lower surface 822 and upper surface 824. The inorganic protection layer 820 may have any thickness T, and, for example, may be up to a micron thick. In practice, however, the film integrity under thermal stress or elastic stress after deposition may limit the maximum thickness. To prevent dust, fluffs, and other debris from adhering to the silicone matrix material of the phosphor layer 806, the inorganic protection layer 820 only needs to be thick enough to shield the silicone matrix material. Using a thin inorganic protection layer 820 protects the phosphor layer 806 from dust, fluffs, and debris without significantly increasing the size, weight, and depth of the pcLED device 800 Thus, inorganic protection layer 820 may, for example, have a thickness T that is less than 100 nm, or for example, less than 50 nm. For example, inorganic protection layer 820 may have a thickness T that is in the range of 20-30 nm.

The inorganic protection layer 820 may also be formed to have certain optical properties. For example, inorganic protection layer 820 may act as an anti-reflection filter. Such an anti-reflection filter may be formed with a single layer having a thickness T of a quarter wavelength (for instance, using a reference wavelength of 550 nm). Or a multi-layer may be used. For example, a multilayer structure with alternating high and low refractive index materials, in which each individual layer is a quarter wavelength thick. The inorganic protection layer 820 may also be designed for spectral selection, for example, a low wavelength pass filter, a high wavelength pass filter, or a band pass filter formed with the combination of low and high wavelength pass filters. In another example, the inorganic protection lay 820 may be formed as to have a semi-reflective optical property over a larger spectral range, for example 380 to 780 nm, that may be used to change the appearance of the “off” state of the LED.

The inorganic protection layer 820 may be formed on the phosphor layer 806 using an Atomic Layer Deposition (ALD) process. ALD is a pulsed chemical vapor deposition (CVD) process which allows the growth of thin layers by applying one atomic layer of a material per cycle. Such process is self-limiting allowing very controlled and conformal coatings or layers.

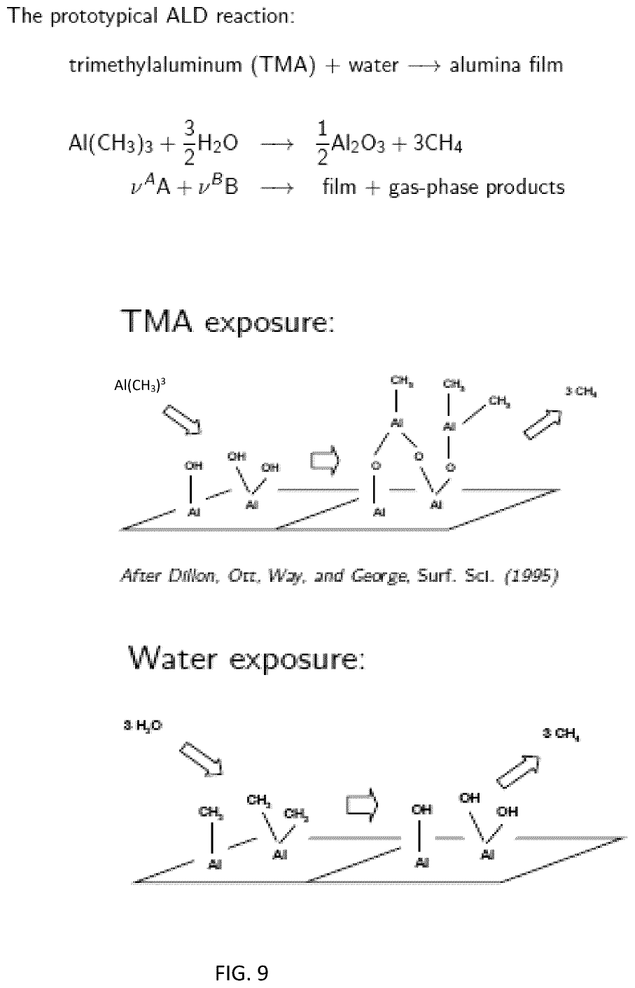

The ALD reaction is split in (at least) two parts. In a first step a metal (oxide) precursor is fed into the reactor and adsorbs and/or reacts with reactive groups on the surfaces, and then substantially all non-reacted or adsorbed precursor molecules are removed by reactor purging. In a second step the oxygen source is fed into the reactor and reacts with the metal source on the particle surfaces, followed by purging of the reactor to remove substantially all remaining oxygen source molecules and hydrolysis products formed by condensation reactions. A prototypical two part ALD reaction using trimethylaluminum (TMA) to form Al₂O₃ is illustrated in FIG. 9.

The two steps lead to formation of an atomic layer (or monolayer) because of the self-limiting nature of the surface reaction. These atomic layer reaction steps are repeated multiple times to form the final ALD layer.

ALD can be performed at low temperatures (50° C.-350° C.) and therefore is compatible with a variety of materials, including, for example, LED and pcLED materials, and in particular silicones used as matrix material in phosphor layer 806. Typical purge times are in the range of 2 sec to 60 sec.

The term metal oxide precursor especially indicates a precursor of the metal oxide. The precursor itself may not be a metal oxide, but may, e.g., include metal organic molecules. Hence, especially the metal (oxide) precursors for ALD may typically include metal halides, alkoxides, amides, and other metal (organic) compounds.

The inorganic protection layer 820 may be, for example, Al₂O₃. An Al₂O₃ layer may be deposited by using an Al(CH₃)₃ (TMA), AlCl3 or HAl(CH₃)₂ precursor in combination with a water, ozone, or oxygen source. Additional details of forming Al₂O₃ coatings using ALD may be found in Dillon, Ott, Way, and George, Surface Science, 322 (1995) 230-242.

In a further embodiment the inorganic protection layer may be formed with another material such SiO₂, SnO₂, CrO₂, ZrO₂, HfO₂, Ta₂0₅, TiO₂, ZnO, TiN, TaN, V₂O₅, PtO₂, B₂O₃, CdS using ALD with precursors and methods understood by persons having ordinary skill in the art. The inorganic protection layer 820 may be formed by a combination of metal oxide materials by forming a multilayer structure as disclosed above.

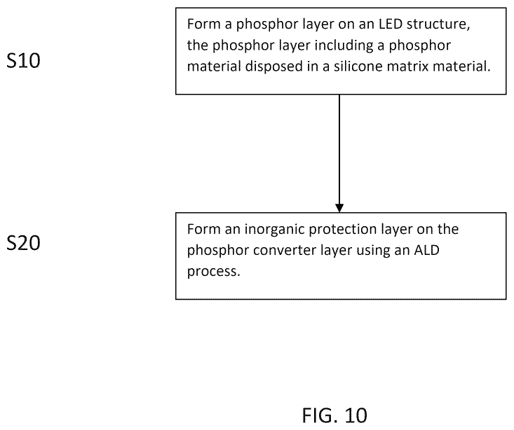

FIG. 10 illustrates a method of forming a pcLED device having a thin inorganic protection layer. At S10 a phosphor layer that includes a phosphor material disposed in a silicone matrix material is formed on an LED structure using methods knowns to persons having ordinary skill in the art. The upper surface of the phosphor layer, opposite the LED structure, is a cured silicone of the matrix material.

At S20, the LED structure having the phosphor layer is put into an ALD reactor, and the inorganic protection layer is formed using the ALD process as disclosed above. Before the atomic layer deposition begins, a short activation treatment may be applied to the silicone surface of the phosphor layer, such as through the use of ultraviolet radiation and/or exposure to ozone, which can increase the accessibility of —OH groups on the surface of the phosphor layer.

An advantage of using ALD to form the thin inorganic protection layer is that it can be performed at temperatures that are low enough so that the formed phosphor layer and LED structure are not damaged or altered by the ALD process. For example, and inorganic protection layer made from Al₂O₃ may be deposited at temperatures of 150° C. (+/−5° C.), and many silicones that may be used as the matrix material in the phosphor conversion layer are stable at that temperature, so forming the inorganic protection layer does not affect the phosphor conversion layer.

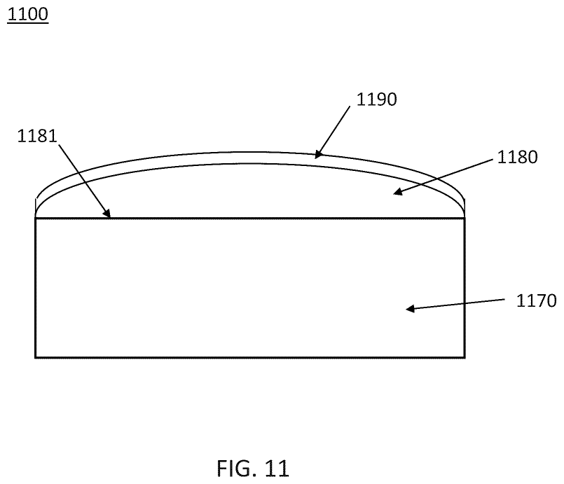

Such an ALD protection layer as described above in FIG. 8 for protecting a phosphor layer formed with a silicone matrix material can be used in LED devices anywhere that a low shore hardness silicone material is used to protect such a silicone layer. That is, the silicone layer protected by the inorganic protection layer does not need to be a phosphor layer including a phosphor material. For example, FIG. 11 shows a device 1100 having an LED structure 1170, a lens 1180 having optical properties formed including a low shore hardness silicone, and an inorganic protection layer 1190 disposed over and in contact with the lens 1180.

The LED structure 1170 may be any of the LED structures described above. LED structure 1170 may include intervening layers (not shown) between the light emitting surface of the LEDs within the LED structure 1170 and the lens 1180. For instance, a phosphor layer or other lenses may be included in LED structure 1170.

Lens 1180 receives light, or a portion of light, emitted from the LED within the LED structure 1170. Although lens 1180 is shown in FIG. 11 with a representative convex shape, lens 1180 is not limited to such a shape, and may have any useful shape for the desired optical properties.

Inorganic protection layer 1190 is disposed on the surface 1181 of the lens 1180, and serves to protect the lens 1180 formed including the low shore hardness silicone from dust, fluffs, and other debris as described above. Inorganic protection layer 1190 may be formed using materials, methods, and thicknesses as described above. An advantage of using ALD for forming such an inorganic protection layer is that the ALD method may be used to form layers that conform to the shape of the underlying silicone layer (i.e., ALD layers may be conformal).

This disclosure is illustrative and not limiting. Further modifications will be apparent to one skilled in the art in light of this disclosure and are intended to fall within the scope of the appended claims.

What is claimed is:

1. A device comprising:
a silicone layer disposed on an LED structure, the silicone layer comprising a phosphor material and a matrix material, the matrix material having a Shore-A hardness of 50 or less; and
an inorganic protection layer disposed on a surface of the silicone layer opposite the LED structure.

2. The device of claim 1, wherein the inorganic protection layer comprises a metal oxide.

3. The device of claim 2, wherein the inorganic protection layer comprises at least one of AlO₃, SiO₂, CrO₂, ZrO₂, HfO₂, and Ta₂O₅.

4. The device of claim 1, wherein the inorganic protection layer is formed by atomic layer deposition.

5. The device of claim 1, wherein the inorganic protection layer has a thickness of less than 100 nm.

6. The device of claim 1, wherein the inorganic protection layer is configured to be transparent to wavelengths in the visible light range.

7. The device of claim 1, wherein the silicone layer is adhesive.

8. The device of claim 1, wherein the inorganic protection layer contacts the silicone layer but not the LED structure.

9. The device of claim 1, wherein the silicone layer is formed into a lens.

10. The device of claim 1, wherein the inorganic protection lay is configured to have optical properties.

11. The device of claim 10, wherein the LED structure comprises an array of LEDs, the array comprising at least two individually addressable light emitting diodes.

12. The device of claim 11 further comprising a display, the display configured to receive light emitted by the array of LEDs.

13. A method of forming a device, the method comprising:
forming a silicone layer on an LED structure, the silicone layer comprising a phosphor material and a matrix material, the matrix material having a Shore-A hardness of 50 or less; and
forming an inorganic protection layer on a surface the silicone layer opposite the LED structure.

14. The method of claim 13, wherein the forming the inorganic protection layer comprises using atomic layer deposition, wherein the inorganic protection layer has a thickness of less than 100 nm.

15. The method of claim 14, further comprising irradiating the silicone layer with ultraviolet light before atomic layer deposition of the inorganic protection layer.

16. The method of claim 14, further comprising exposing the silicone layer to ozone before atomic layer deposition of the inorganic protection layer.

17. The method of claim 13, wherein forming inorganic protection layer comprises contacting the silicone layer but not the LED structure.

18. The method of claim 13, wherein the inorganic protection layer comprises at least one of AlO₃, SiO₂, CrO₂, ZrO₂, HfO₂, and Ta₂O₅.

19. The method of claim 13, wherein the silicon layer is adhesive.

20. The method of claim 13. wherein the inorganic protection layer is configured to be transparent to wavelengths in the visible light range.
